(19) United States
(12) Patent Application Publication
(10) Pub. No.: US 2026/0107777 A1
(43) Pub. Date: Apr. 16, 2026

(54) SEMICONDUCTOR PACKAGE

(71) Applicant: Samsung Electronics Co., Ltd., Suwon-si (KR)

(72) Inventors: Keun Young LEE, Suwon-si (KR); Dong Ok KWAK, Suwon-si (KR); Tae-Young LEE, Suwon-si (KR)

(21) Appl. No.: 19/268,319

(22) Filed: Jul. 14, 2025

(30) Foreign Application Priority Data
Oct. 11, 2024 (KR) 10-2024-0138959

(51) Int. Cl. H01L 23/552; H01L 23/31; H01L 23/498; H01L 25/16

(52) U.S. Cl. CPC H10W 42/20; H10W 70/66; H10W 70/685; H10W 74/111; H10W 90/00

(57) ABSTRACT

A semiconductor package is provided. A semiconductor package comprises a substrate, a plurality of semiconductor chips disposed on the substrate, a plurality of first conductive structures surrounding the semiconductor chips, a plurality of second conductive structures disposed on the first conductive structures and electrically connecting the first conductive structures, a mold layer encapsulating the semiconductor chips, the first conductive structures, and portions of the second conductive structures, and a shielding film disposed on the mold layer and in contact with uppermost portions of the second conductive structures that are not encapsulated by the mold layer, wherein the semiconductor chips include a first semiconductor chip, and a second semiconductor chip spaced apart from the first semiconductor chip, and upper surfaces of the first conductive structures are positioned below an upper surface of the second semiconductor chip.

### CROSS-REFERENCE TO RELATED APPLICATION

This application claims priority to Korean Patent Application No. 10-2024-0138959 filed on Oct. 11, 2024 in the Korean Intellectual Property Office, and all the benefits accruing therefrom under 35 U.S.C. 119, the contents of which in their entirety are herein incorporated by reference.

### BACKGROUND

### 1. Field

The present disclosure relates to a semiconductor package.

### 2. Description of the Related Art

With the advancement of the electronics industry, the demand for higher functionality, faster speed, and miniaturization of electronic devices is increasing. In response to these trends, methods such as stacking and mounting multiple semiconductor chips on a single package substrate or stacking one package on top of another package can be utilized. For example, semiconductor packages in the form of package-in-package (PIP) or package-on-package (POP) may be employed. Furthermore, research and development efforts are continuously being made on electromagnetic wave shielding technologies to prevent electromagnetic interference (EMI) between components within electronic devices.

### SUMMARY

Aspects of the present disclosure provide a semiconductor package with improved process efficiency.

Aspects of the present disclosure also provide a semiconductor package with enhanced electromagnetic interference (EMI) shielding characteristics.

However, the inventive concept is not restricted/limited to those set forth above. The above and other aspects of the present disclosure will become more apparent to one of ordinary skill in the art to which the present disclosure pertains by referencing the detailed description of the present disclosure given below.

According to an aspect of the present disclosure, there is provided a semiconductor package comprising a substrate, a plurality of semiconductor chips disposed on the substrate, a plurality of first conductive structures surrounding the semiconductor chips, a plurality of second conductive structures disposed on the first conductive structures and electrically connecting the first conductive structures, a mold layer encapsulating the semiconductor chips, the first conductive structures, and portions of the second conductive structures, and a shielding film disposed on the mold layer and in contact with uppermost portions of the second conductive structures that are not encapsulated by the mold layer, wherein the semiconductor chips include a first semiconductor chip, and a second semiconductor chip spaced apart from the first semiconductor chip, and upper surfaces of the first conductive structures are positioned below an upper surface of the second semiconductor chip.

According to the aforementioned and other embodiments of the present disclosure, there is provided a method of manufacturing a semiconductor package, comprising disposing a plurality of semiconductor chips on a substrate, disposing a plurality of first conductive structures surrounding the semiconductor chips, disposing second conductive structures on the first conductive structures to electrically connect the first conductive structures, disposing a mold layer encapsulating the semiconductor chips, the first conductive structures, and portions of the second conductive structures excluding uppermost portions of the second conductive structures, and disposing, on the mold layer, a shielding film in contact with the uppermost portions of the second conductive structures, wherein the first conductive structures include a first conductive unit, a second conductive unit, and a third conductive unit that are adjacent to one another, and the second conductive structures include a first wire having both ends in contact with the first conductive unit and the second conductive unit respectively, and a second wire having both ends in contact with the first conductive unit and the third conductive unit respectively.

According to the aforementioned and other embodiments of the present disclosure, a semiconductor package comprising a substrate, a plurality of semiconductor chips disposed on the substrate, a plurality of first conductive structures surrounding the semiconductor chips, a plurality of second conductive structures disposed on the first conductive structures and electrically connecting adjacent first conductive structures, a mold layer encapsulating the semiconductor chips, the first conductive structures, and portions of the second conductive structures, a shielding film disposed on the mold layer and in contact with uppermost portions of the second conductive structures that are not encapsulated by the mold layer, and external connection terminals disposed on a lower surface of the substrate and configured to electrically connect the semiconductor package to an outside of the semiconductor package, wherein the semiconductor chips include a first semiconductor chip, and a second semiconductor chip spaced apart from the first semiconductor chip and having an upper surface at a higher level than an upper surface of the first semiconductor chip, the first conductive structures are configured to be electrically connected to ground via the external connection terminals, upper surfaces of the first conductive structures are positioned at a lower level than the upper surface of the second semiconductor chip, the first conductive structures include a first conductive unit, a second conductive unit, and a third conductive unit adjacent each other, a distance between the first conductive unit and the second conductive unit is in a range from 1/20 to 1/50 of an operating wavelength of the semiconductor chips, the second conductive structures include a first wire having both ends in contact with the first conductive unit and the second conductive unit respectively, and a second wire having both ends in contact with the second conductive unit and the third conductive unit respectively, the first wire includes a first extension portion sealed by the mold layer and in contact with the first conductive unit, a second extension portion sealed by the mold layer and in contact with the second conductive unit, and a bent portion connecting the first extension portion and the second extension portion and in contact with the shielding film, and the shielding film is electrically connected to the first wire and the second wire.

It should be noted that the effects of the inventive concept are not limited to those described above, and other effects of the present disclosure will be apparent from the following description.

### BRIEF DESCRIPTION OF THE DRAWINGS

The above and other aspects and features of the present disclosure will become more apparent by describing in detail exemplary embodiments thereof with reference to the attached drawings, in which:

FIG. 1 is a top view illustrating a semiconductor package according to some embodiments.

FIG. 2 is a cross-sectional view taken along line A-A′ of FIG. 1.

FIG. 3 is a cross-sectional view taken along line B-B′ of FIG. 1.

FIG. 4 is a cross-sectional view taken along line C-C′ of FIG. 1.

FIG. 5 is an enlarged view of region D of FIG. 3.

FIG. 6 is an enlarged view of region E of FIG. 3.

FIGS. 7 through 12 are cross-sectional views taken along a line corresponding to line B-B′ of FIG. 1, illustrating a method of manufacturing a semiconductor package according to some embodiments.

FIG. 13 is a cross-sectional view taken along line B-B′ of FIG. 1, illustrating the effects of a semiconductor package according to some embodiments.

FIGS. 14 and 15 are top views illustrating semiconductor packages according to some embodiments.

### DETAILED DESCRIPTION

Embodiments of the present disclosure will hereinafter be described in detail with reference to the accompanying drawings. The same reference numerals are used for the same components in the drawings, and redundant/duplicate explanations of these components will be omitted.

Throughout the specification, when a component is described as “including” a particular element or group of elements, it is to be understood that the component is formed of only the element or the group of elements, or the element or group of elements may be combined with additional elements to form the component, unless the context clearly and/or explicitly describes the contrary.

As used herein, components described as being “electrically connected” are configured such that an electrical signal can be transferred from one component to the other (although such electrical signal may be attenuated in strength as it is transferred and may be selectively transferred).

Spatially relative terms, such as “beneath,” “below,” “lower,” “above,” “upper,” “top,” “bottom,” “front,” “rear,” “horizontal,” “vertical,” and the like, may be used herein for ease of description to describe positional relationships, such as illustrated in the figures, for example. It will be understood that the spatially relative terms encompass different orientations of the device in addition to the orientation depicted in the figures.

It will be understood that when an element is referred to as being “connected” or “coupled” to or “on” another element, it can be directly connected or coupled to or on the other element or intervening elements may be present. In contrast, when an element is referred to as being “directly connected” or “directly coupled” to another element, or as “contacting” or “in contact with” another element (or using any form of the word “contact”), there are no intervening elements present at the point of contact.

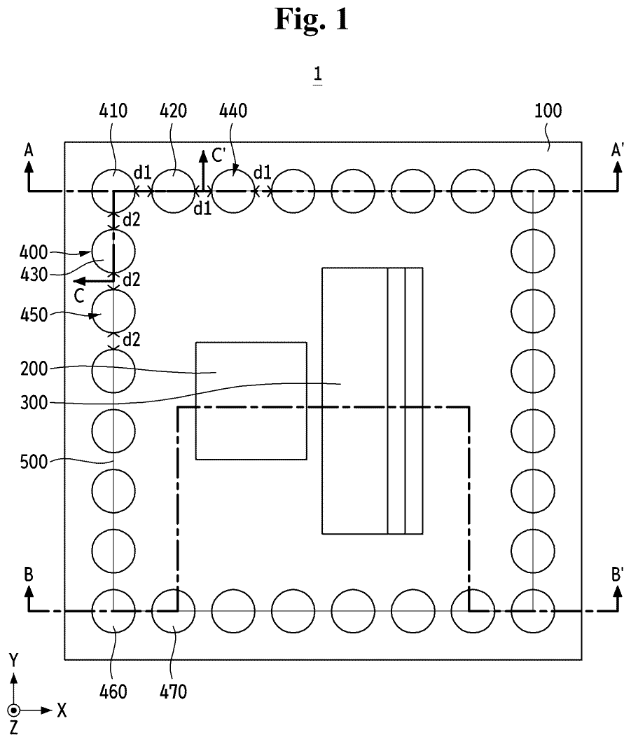

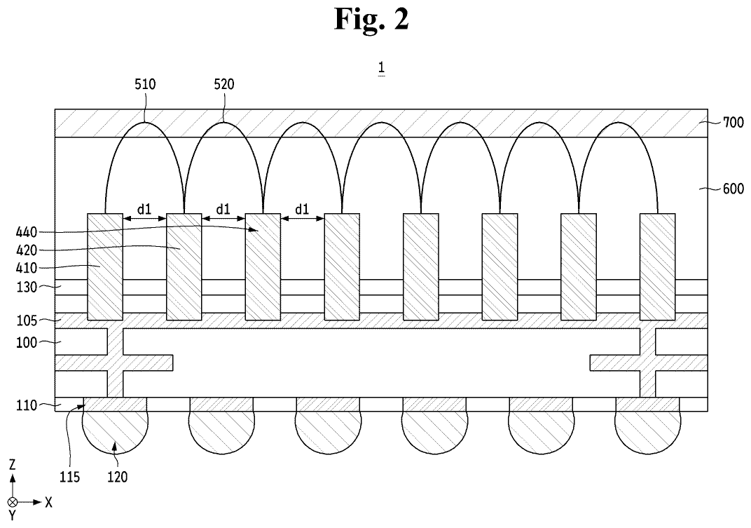

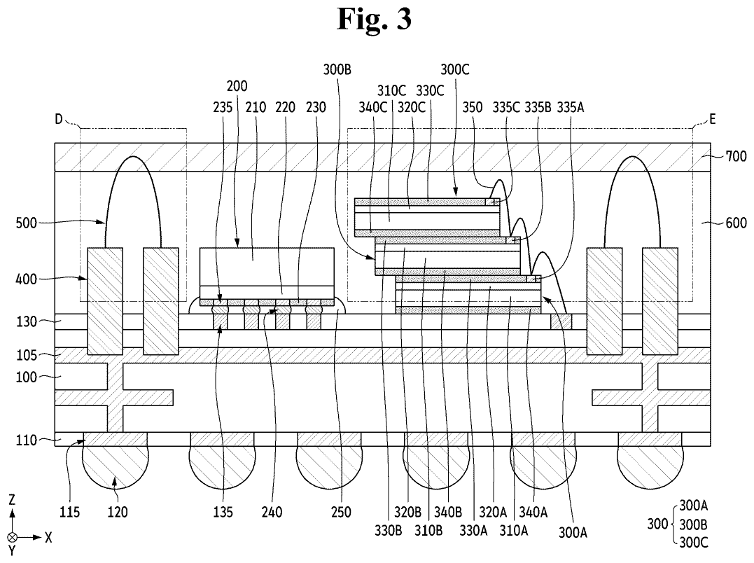

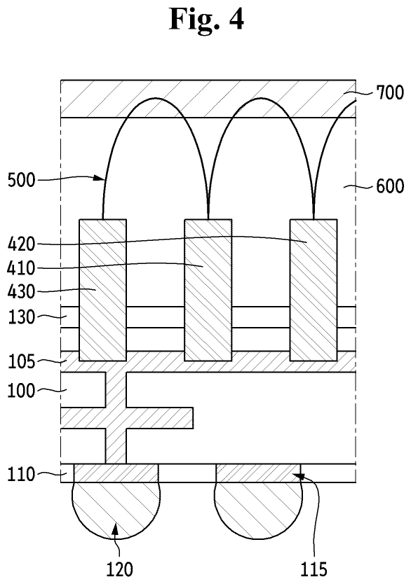

FIG. 1 is a top view illustrating a semiconductor package according to some embodiments. FIG. 2 is a cross-sectional view taken along line A-A′ of FIG. 1. FIG. 3 is a cross-sectional view taken along line B-B′ of FIG. 1. FIG. 4 is a cross-sectional view taken along line C-C′ of FIG. 1.

Referring to FIGS. 1 through 4, a semiconductor package 1 may include a package substrate 100, a first semiconductor chip 200, a second semiconductor chip 300, first conductive structures 400, second conductive structures 500, a sealing member 600, and a shielding film 700.

The semiconductor package 1 may be a multi-chip package (MCP) such as universal flash storage (UFS), which includes different types of semiconductor chips. The semiconductor package 1 may be a system-in-package (SIP) where multiple semiconductor chips are stacked or arranged in a single package to provide an independent function.

The package substrate 100 may be a substrate for semiconductor packages, including a printed circuit board (PCB), a ceramic substrate, a glass substrate, or a tape-based wiring substrate.

The first semiconductor chip 200 and the second semiconductor chip 300 may be disposed on a surface (i.e., the top surface) of the package substrate 100. The first semiconductor chip 200 may be mounted on the package substrate 100 by flip-chip bonding using a plurality of microbumps 240.

The first semiconductor chip 200 may include a semiconductor substrate 210, a wiring structure 220, and a protective layer 230.

The semiconductor substrate 210 may include, for example, a semiconductor element such as silicon (Si) or germanium (Ge), or a compound semiconductor such as silicon carbide (SiC), gallium arsenide (GaAs), indium arsenide (InAs), or indium phosphide (InP).

The wiring structure 220 may be disposed on the lower surface of the semiconductor substrate 210. The wiring structure 220 may include various types of active elements and/or passive elements. For example, the wiring structure 220 may include field-effect transistors (FETs) such as planar FETs or FinFETs, memory elements such as flash memories, dynamic random-access memories (DRAMs), static random-access memories (SRAMs), electrically erasable programmable read-only memories (EEPROMs), phase-change random-access memories (PRAMs), magnetoresistive random-access memories (MRAMs), ferroelectric random-access memories (FeRAMs), or resistive random-access memories (RRAMs), logic elements such as AND, OR, or NOT gates, and active and/or passive elements such as system large scale integrations (LSIs), CMOS image sensor (CISs), or microelectro-mechanical systems (MEMSs).

Connection pads 235 may be disposed on the lower surface of the wiring structure 220. The protective layer 230 may be disposed around the connection pads 235. For example, the protective layer 230 and the connection pads 235 may be disposed at the same level such that the protective layer 230 and the connection pads 235 overlap in a horizontal direction.

The connection pads 235 may be electrically connected to first electrode pads 135 of the package substrate 100 via the microbumps 240. The first electrode pads 135 may be pads formed on an upper surface of the package substrate 100.

The protective layer 230 may be disposed on the lower surface of the wiring structure 220. The protective layer 230 may be formed of a photosensitive material such as photosensitive polyimide (PSPI).

An underfill 250 may be positioned between the upper surface of the package substrate 100 and the first semiconductor chip 200. The underfill 250 may surround the microbumps 240. For example, the underfill 250 may contact side surfaces of the microbumps 240.

The first semiconductor chip 200 may be a logic chip that includes a logic circuit. The first semiconductor chip 200 may serve as a controller for controlling memory chips. The first semiconductor chip 200 may be a processor chip such as an application-specific integrated circuit (ASIC), an application processor (AP), or a host such as a central processing unit (CPU), a graphics processing unit (GPU), or a system-on-chip (SOC).

The semiconductor package 1 may include a plurality of second semiconductor chips 300 (e.g., 300A, 300B, and 300C as shown in FIG. 3). The second semiconductor chips 300A, 300B, and 300C may include semiconductor substrates 310A, 310B, and 310C, respectively, wiring structures 320A, 320B, and 320C, respectively, protective layers 330A, 330B, and 330C, respectively, and sets of connection pads 335A, 335B, and 335C, respectively. For example, each of the second semiconductor chips 300 may include a plurality of connection pads 335A, 335B, or 335C.

The second semiconductor chips 300 may be fixed on the package substrate 100 via adhesive films 340A, 340B, and 340C. The adhesive films 340A, 340B, and 340C may be, for example, die adhesive films (DAFs), but the inventive concept is not limited thereto.

The semiconductor substrates 310A, 310B, and 310C may include a semiconductor element such as Si or Ge, or a compound semiconductor such as SiC, GaAs, InAs, or InP.

The wiring structures 320A, 320B, and 320C may be disposed on the upper surfaces of the semiconductor substrates 310A, 310B, and 310C. The wiring structures 320A, 320B, and 320C may include various types of active and/or passive elements. For example, the wiring structures 320A, 320B, and 320C may each include FETs such as planar FETs or FinFETs, memory elements such as flash memories, DRAMs, SRAMs, EEPROMs, PRAMs, MRAMs, FeRAMs, or RRAMs, logic elements such as AND, OR, or NOT gates, and active and/or passive elements such as LSIs, CISs, or MEMSs.

The sets of connection pads 335A, 335B, and 335C may be disposed on the upper surfaces of the wiring structures 320A, 320B, and 320C. The protective layers 330A, 330B, and 330C may be disposed around the sets of connection pads 335A, 335B, and 335C. For example, the protective layers 330A, 330B, an d330C and the connection pads 335A, 335B, and 335C may be disposed at the same level, respectively, such that the protective layers 330A, 330B, an d330C and the connection pads 335A, 335B, and 335C overlap in a horizontal direction respectively.

The sets of connection pads 335A, 335B, and 335C may be electrically connected to the first electrode pads 135 of the package substrate 100 via wires 350.

The protective layers 330A, 330B, and 330C may be disposed on the top surfaces of the wiring structures 320A, 320B, and 320C. The protective layers 330A, 330B, and 330C may be formed of a photosensitive material such as PSPI.

The second semiconductor chip 300 may include a memory chip that contains a memory circuit. For example, the second semiconductor chip 300 may include a volatile memory device such as an SRAM device or a DRAM device, and a non-volatile memory device such as a flash memory, a PRAM device, an MRAM device, or an RRAM device.

The first conductive structures 400 may be disposed on the package substrate 100. The first conductive structures 400 may surround the first semiconductor chip 200 and the second semiconductor chips 300.

For example, the first conductive structures 400 may include a first conductive unit 410, a second conductive unit 420, and a third conductive unit 430 that are adjacent to one another.

Referring to FIGS. 1 and 2, the second conductive unit 420 may be adjacent to the first conductive unit 410 in a first direction X. A fourth conductive unit 440 may be adjacent to the second conductive unit 420 in the first direction X, and the first conductive structures 400 may include a plurality of fourth conductive units 440 arranged in the first direction X. The distance between the first conductive unit 410 and the second conductive unit 420 adjacent to the first conductive unit 410 may be d1. The distance between the second conductive unit 420 and the fourth conductive unit 440 adjacent to the second conductive unit 420 may be d1. The distance between adjacent fourth conductive structures 440 may be d1. Thus, first conductive structures 400 arranged in the first direction X may all be arranged at uniform/regular intervals. Each conductive unit in the present disclosure may be a conductive block (e.g., piece of conductive material) in the form of a post, pillar, cylinder, or column, for example.

In the present disclosure, when a first element is adjacent to a second element, the first element may be the closest one to the second element among elements identical to the first element in certain direction. For example, when the first conductive unit 410, the second conductive unit 420, and the third conductive unit 430 are adjacent to one another, the first conductive unit 410 and the second conductive unit 420 may be the closest conductive structures 400 to each other in a direction where the first and second conductive units 410 and 420 are arranged and the first conductive unit 410 and the third conductive unit 430 may be the closest conductive structures 400 to each other in a direction where the first and third conductive units 410 and 430 are arranged.

Referring to FIGS. 1 and 4, the first conductive unit 410 may be adjacent to the third conductive unit 430 in a second direction Y. A fifth conductive unit 450 may be adjacent to the third conductive unit 430 in the second direction Y, and the first conductive structures 400 may include a plurality of fifth conductive units 450 arranged in the second direction Y. The distance between the first conductive unit 410 and the third conductive unit 430 adjacent to the first conductive unit 410 may be d2. The distance between the third conductive unit 430 and the fifth conductive unit 450 adjacent to the third conductive unit 430 may be d2. The distances between adjacent fifth conductive units 450 may be d2. Thus, first conductive structures 400 arranged in the second direction Y may all be arranged at uniform/regular intervals.

Here, d1 and d2 may be in a range from 1/50 to 1/20 of an operating wavelength λ required and/or used for the operation of the first semiconductor chip 200 and/or the second semiconductor chip 300. For example, the operating wavelength λ may be a value determined based on the frequency of a reference clock provided from the first semiconductor chip 200 to the second semiconductor chip 300. For example, the operating wavelength λ may be the same as a distance that an electromagnetic wave travels in a second in space divided by the frequency of the reference clock.

In some embodiments, d1 and d2 may have the same value. For example, the first conductive structures 400 surrounding the first semiconductor chip 200 and the second semiconductor chip 300 may all be arranged at equal intervals, e.g., in the first and second directions X and Y, but the inventive concept is not limited thereto.

The first conductive structures 400 may be single continuous pieces of conductive material in some embodiments. The first conductive structures 400 may include copper (Cu). For example, the first conductive structures 400 may be Cu posts. The first conductive structures 400 may be electrically connected to an internal wiring structure 105 and thereby electrically connected to the package substrate 100.

Referring to FIG. 3, in some embodiments, the first conductive structures 400 may be electrically connected to a ground via the second conductive structures 500 and the external connection terminals 120 disposed on the package substrate 100.

Referring to FIGS. 1 and 2, the second conductive structures 500 may be disposed on the first conductive structures 400. The second conductive structures 500 may physically and electrically connect adjacent first conductive structures 400 in a wire form. For example, the second conductive structures 500 may be conductive wires.

In some embodiments, the second conductive structures 500 may include a first wire 510 and a second wire 520. The first wire 510 may physically and electrically connect the first conductive unit 410 and the second conductive unit 420. The second wire 520 may physically and electrically connect the second conductive unit 420 and the fourth conductive unit 440 adjacent to the second conductive unit 420.

For example, one end of the first wire 510 may contact the first conductive unit 410, and the other end of the first wire 510 may contact the second conductive unit 420. One end of the second wire 520 may contact the second conductive unit 420, and the other end of the second wire 520 may contact the fourth conductive unit 440. Similarly, the adjacent first conductive structures 400 disposed within the semiconductor package 1 may be physically and electrically connected via the second conductive structures 500.

Referring again to FIGS. 1 and 4, the semiconductor package 1 may include a plurality of external connection terminals 120 on the other surface (i.e., the lower surface) of the package substrate 100. The external connection terminals 120 may be formed of a conductive material and may have a shape such as a ball or pin shape. For example, the external connection terminals 120 may be solder balls or bumps.

The package substrate 100 may include the internal wiring structure 105. The internal wiring structure 105 may be arranged in a plurality of layers. For example, the internal wiring structure 105 may be disposed in two layers, but the inventive concept is not limited thereto. Alternatively, in another example, the internal wiring structure 105 may be disposed in one layer or three layers. For example, the internal wiring structure 105 may include one, two, or three layers of conductive patterns. The internal wiring structure 105 may include conductive vias electrically connecting the layers of the conductive patterns when the internal wiring structure includes two or more layers of the conductive patterns.

The package substrate 100 may further include a first protective film 130 on one surface and a second protective film 110 on the other surface. The first electrode pads 135 may be disposed on the one surface of the package substrate 100 and exposed without being covered by the first protective film 130. The exposed first electrode pads 135 may be electrically connected to the connection pads 335 of the second semiconductor chip 300 via the wires 350. The second electrode pads 115 may be disposed on the other surface of the package substrate 100 and exposed without being covered by the second protective film 110. The exposed second electrode pads 115 may be directly connected to the external connection terminals 120.

The sealing member 600 may encapsulate the package substrate 100, the first semiconductor chip 200, the second semiconductor chip 300, the first conductive structures 400, and portions of the second conductive structures 500. For example, the sealing member 600 may be a mold layer covering the first semiconductor chip 200, the second semiconductor chips 300, the first conductive structures 400, and portions of the second conductive structures 500. The sealing member 600 may include, for example, an epoxy molding compound (EMC), but the inventive concept is not limited thereto.

The shielding film 700 may be disposed on the sealing member 600. The shielding film 700 may include a conductive material such as metal. The shielding film 700 may be formed using a spray method.

In some embodiments, the shielding film 700 may be electrically connected to the second conductive structures 500, and may be electrically connected to the first conductive structures 400 through the second conductive structures 500.

In some embodiments, the shielding film 700 may shield/absorb electromagnetic waves applied from outside the semiconductor package 1 or electromagnetic waves emitted from inside the semiconductor package 1. For example, the shielding film 700 may absorb electromagnetic waves and release them externally through the second conductive structures 500, the first conductive structures 400, and the internal wiring structure 105.

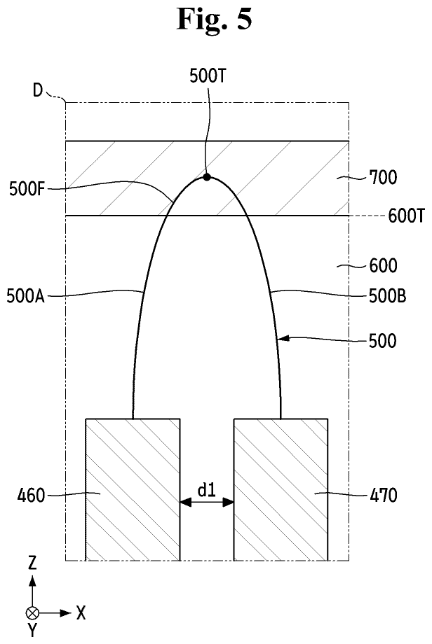

FIG. 5 is an enlarged view of region D of FIG. 3.

Referring to FIGS. 3 and 5, each second conductive structure 500 may include a first extension portion 500A, a second extension portion 500B, and a bent portion 500F. For example, each second conductive structure 500 may have a curved shape, wherein the radius of curvature of each of the first extension portion 500A and second extension portion 500B is larger than a radius of curvature of the bent portion 500F.

The second conductive structure 500 may physically and electrically connect adjacent first conductive structures 400.

In some embodiments, the second conductive structures 500 may physically and electrically connect a sixth conductive unit 460 and a seventh conductive unit 470. For example, the first extension portion 500A may contact the sixth conductive unit 460. The second extension portion 500B may contact the seventh conductive unit 470. The first extension portion 500A and the second extension portion 500B may be connected via the bent portion 500F. The first extension portion 500A and the second extension portion 500B may be positioned below an upper surface 600T of the sealing member 600 in a third direction Z and may be sealed/surrounded by the sealing member 600.

The bent portion 500F may not be sealed/covered by the sealing member 600 and may contact the shielding film 700. For example, the bent portion 500F may be surrounded by the shielding film 700. The bent portion 500F may include an uppermost portion 500T of the second conductive structure 500. For example, the uppermost portion 500T of the second conductive structure 500 may be positioned higher than the upper surface 600T of the sealing member 600 in the third direction Z.

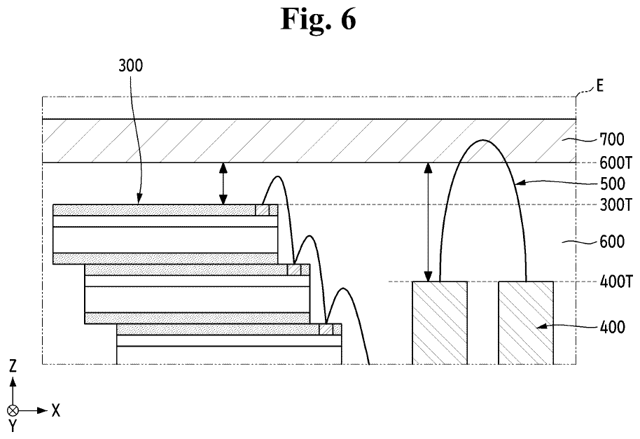

FIG. 6 is an enlarged view of region E of FIG. 3.

Referring to FIGS. 3 and 6, the second semiconductor chip 300 may have a greater height in the third direction Z than the first semiconductor chip 200. Upper surfaces 400T of the first conductive structures 400 may be positioned lower in the third direction Z than an upper surface 300T of the second semiconductor chip 300. For example, the second semiconductor chips 300 may be stacked on the package substrate 100 in a vertical direction (e.g., the Z-direction), and the second semiconductor chip 300 disposed at the uppermost position of the stacked second semiconductor chips 300 may be at a higher level than the first semiconductor chip 200. For example, the upper surface 300T of the uppermost second semiconductor chip 300 may be at a higher level than an upper surface of the first semiconductor chip 200.

However, as disclosed herein, by additionally disposing the second conductive structures 500 on the first conductive structures 400, electromagnetic waves can be effectively shielded/blocked in a thick semiconductor package 1 that includes highly stacked second semiconductor chips 300, compared to a case when only the first conductive structures 400 or the second conductive structures 500 are used individually.

In some embodiments, the upper surface of the first semiconductor chip 200 may be positioned lower in the third direction Z than the upper surfaces 400T of the first conductive structures 400, but the inventive concept is not limited thereto. Alternatively, in another example, the upper surface of the first semiconductor chip 200 may be positioned higher in the third direction Z than the upper surfaces 400T of the first conductive structures 400.

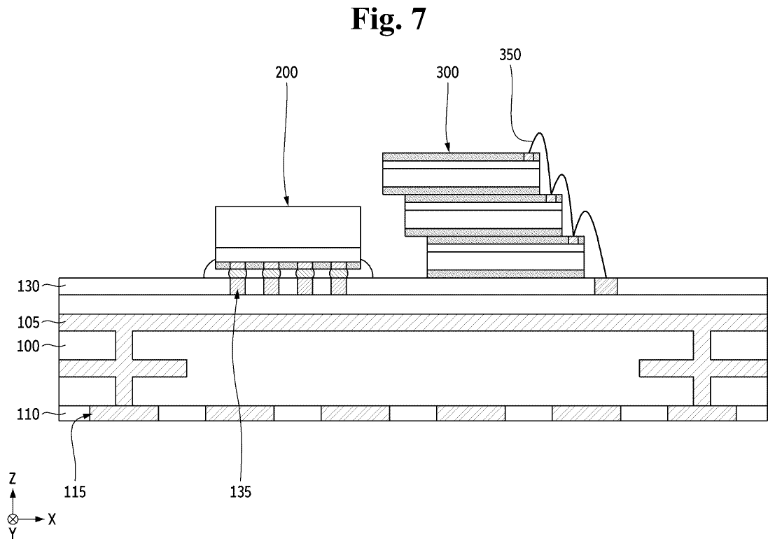

FIGS. 7 through 12 are cross-sectional views taken along a line corresponding to line B-B′ of FIG. 1, illustrating a method of manufacturing a semiconductor package according to some embodiments.

Referring to FIG. 7, a first semiconductor chip 200 and second semiconductor chips 300 may be disposed on a surface (i.e., the upper surface) of a package substrate 100. For example, the first semiconductor chip 200 may be mounted on the package substrate 100 using a flip-chip bonding method. The second semiconductor chips 300 may be fixed on the package substrate 100 via adhesive films 340A, 340B, and 340C. The adhesive films 340A, 340B, and 340C may be, for example, DAFs, but the inventive concept is not limited thereto.

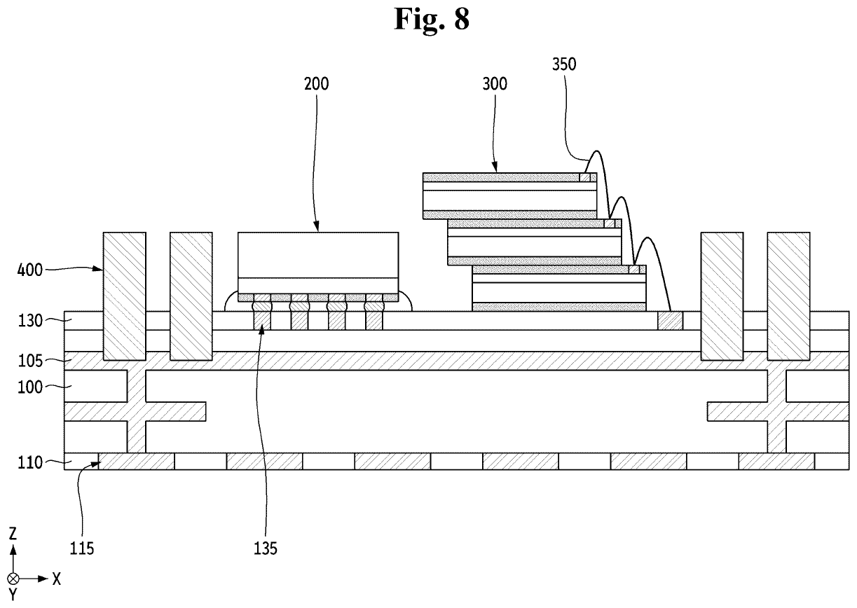

Referring to FIGS. 1 and 8, first conductive structures 400 may be disposed on the package substrate 100. The first conductive structures 400 may surround the first semiconductor chip 200 and the second semiconductor chips 300. For example, the first conductive structures 400 may be disposed along the edges of the package substrate 100 at regular intervals (e.g., d1 or d2).

Here, d1 and d2 may be in a range from 1/50 to 1/20 of an operating wavelength λ required and/or used for the operation of the first semiconductor chip 200 and/or the second semiconductor chips 300. For example, the operating wavelength λ may be a value determined based on the frequency of a reference clock provided from the first semiconductor chip 200 to the second semiconductor chip 300. For example, the operating wavelength λ may be the same as a value that the speed of light is divided by the frequency of the reference clock.

The first conductive structures 400 may include Cu. For example, the first conductive structures 400 may be Cu posts.

The first conductive structures 400 may be electrically connected to an internal wiring structure 105 and thereby electrically connected to the package substrate 100.

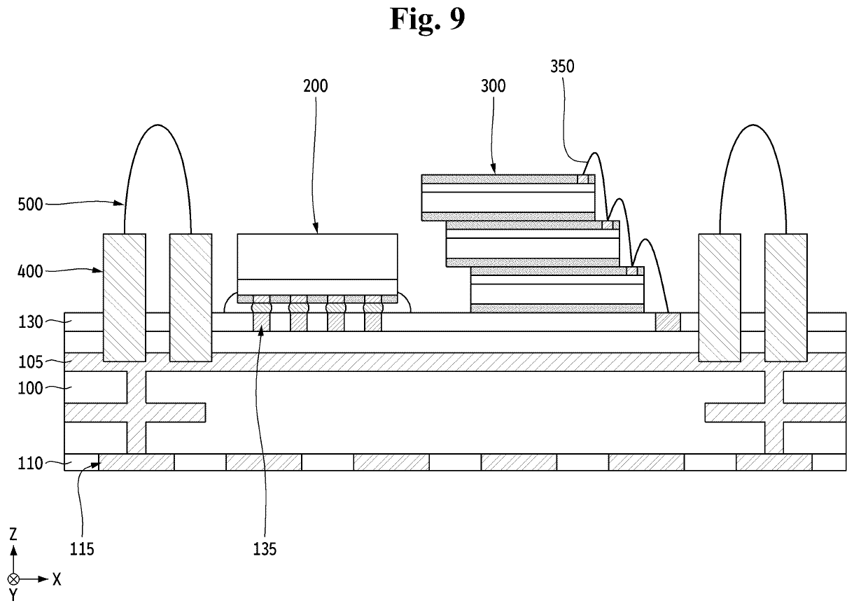

Referring to FIGS. 1 and 9, second conductive structures 500 may be disposed on the first conductive structures 400. The second conductive structures 500 may physically and electrically connect adjacent first conductive structures 400.

For example, both ends of each of the second conductive structures 500 may respectively contact two adjacent first conductive structures 400. Through this, all the first conductive structures 400 within a semiconductor package 1 may be physically and electrically connected to each other.

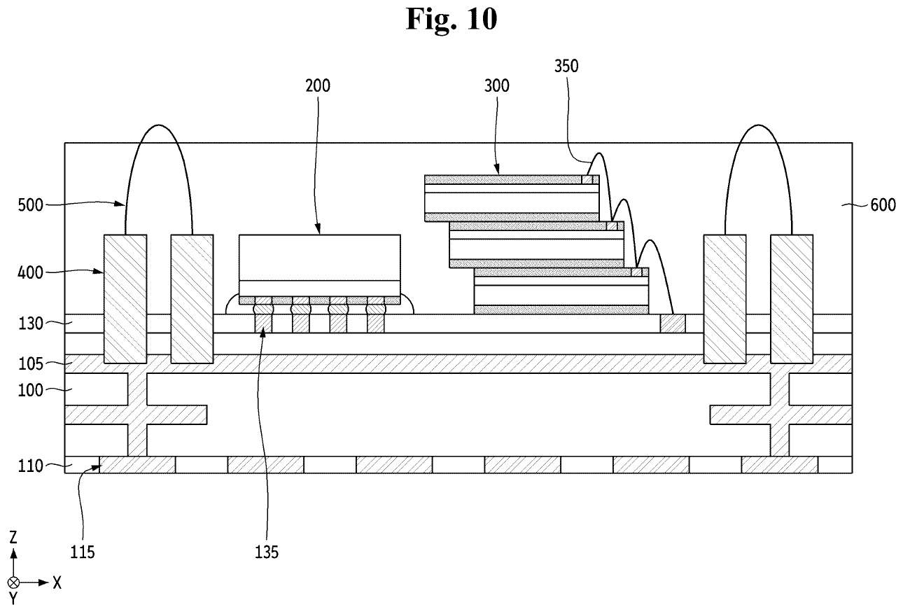

Referring to FIGS. 5 and 10, a sealing member 600 may be disposed on the package substrate 100 to encapsulate the package substrate 100, the first semiconductor chip 200, the second semiconductor chips 300, the first conductive structures 400, and portions of the second conductive structures 500.

For example, each of the second conductive structures 500 may include a first extension portion 500A, a second extension portion 500B, and a bent portion 500F. The first extension portion 500A and the second extension portion 500B may be positioned below an upper surface 600T of the sealing member 600 in a third direction Z and may be sealed/surrounded by the sealing member 600. However, the bent portion 500F may not be sealed/covered by the sealing member 600 and may be exposed externally. The bent portion 500F may include an uppermost portion 500T of the corresponding second conductive structure 500. For example, the uppermost portions 500T of the second conductive structures 500 may be positioned higher in the third direction Z than the upper surface 600T of the sealing member 600.

The sealing member 600 may include, for example, an EMC, but the inventive concept is not limited thereto.

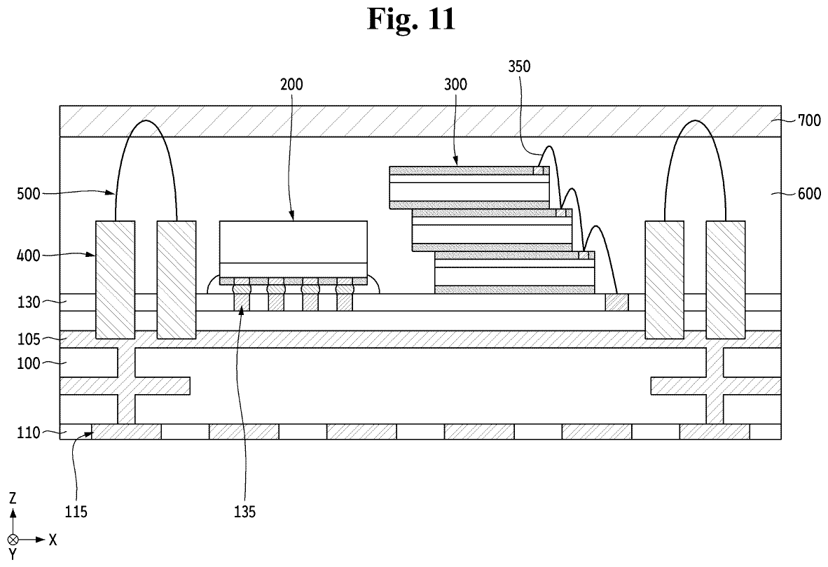

Referring to FIG. 11, a shielding film 700 may be disposed on the sealing member 600 and the bent portions 500F of the second conductive structures 500. The shielding film 700 may include a conductive material such as metal. The shielding film 700 may be formed using a spray method.

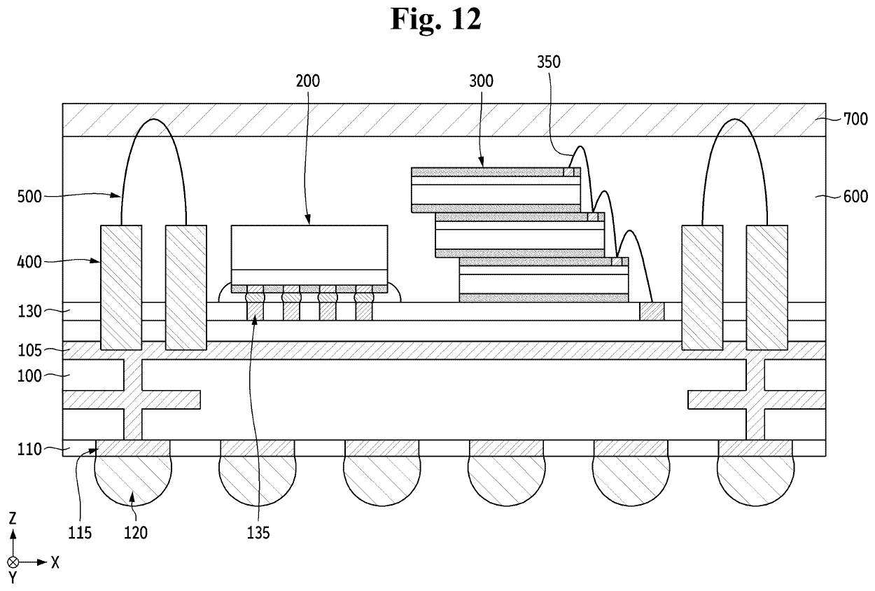

Referring to FIG. 12, a plurality of external connection terminals 120 may be attached to second electrode pads 115 of the package substrate 100. The external connection terminals 120 may electrically connect the semiconductor package 1 to the outside.

In some embodiments, the external connection terminals 120 may be formed of a conductive material and may have a shape such as a ball or pin shape. The external connection terminals 120 may be formed of a material such as Cu, aluminum (Al), silver (Ag), tin (Sn), gold (Au), or solder, but the inventive concept is not limited thereto.

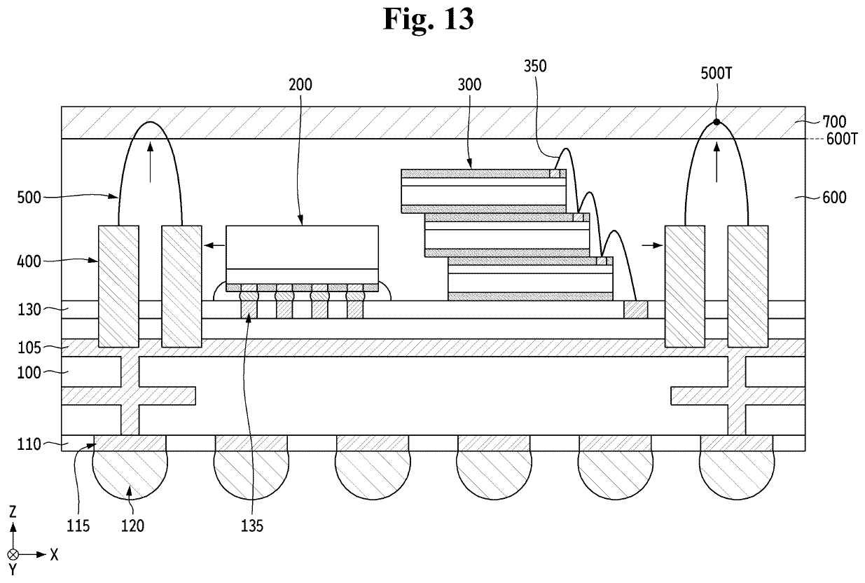

FIG. 13 is a cross-sectional view taken along line A-A′ of FIG. 1, illustrating the effects of a semiconductor package according to some embodiments.

Referring to FIGS. 1 and 13, a semiconductor package 1 may include first conductive structures 400 and second conductive structures 500 for shielding electromagnetic waves applied from outside the semiconductor package 1 or emitted from a first semiconductor chip 200 and/or a second semiconductor chip 300. By disposing the second conductive structures 500 on the first conductive structures 400, uppermost portions 500T of the second conductive structures 500 may be positioned higher in a third direction Z than an upper surface 600T of a sealing member 600. By disposing a shielding film 700 on the upper surface 600T of the sealing member 600, where the second conductive structures 500 are exposed, using a spray method, the second conductive structures 500 and the shielding film 700 may be electrically connected to shield/absorb electromagnetic waves generated from inside and/or transferred from outside the semiconductor package 1.

For example, the second conductive structures 500 and the shielding film 700 may be electrically connected without the need of a process of drilling or grinding the sealing member 600 to electrically connect the second conductive structures 500 and the shielding film 700. Therefore, a semiconductor package 1 with improved process efficiency can be provided.

Additionally, by disposing the second conductive structures 500 on the first conductive structures 400, electromagnetic waves can be effectively shielded/absorbed in a thick semiconductor package 1 that includes a tall/high semiconductor chip or highly stacked semiconductor chips, compared to a case when only the first conductive structures 400 or the second conductive structures 500 are used individually.

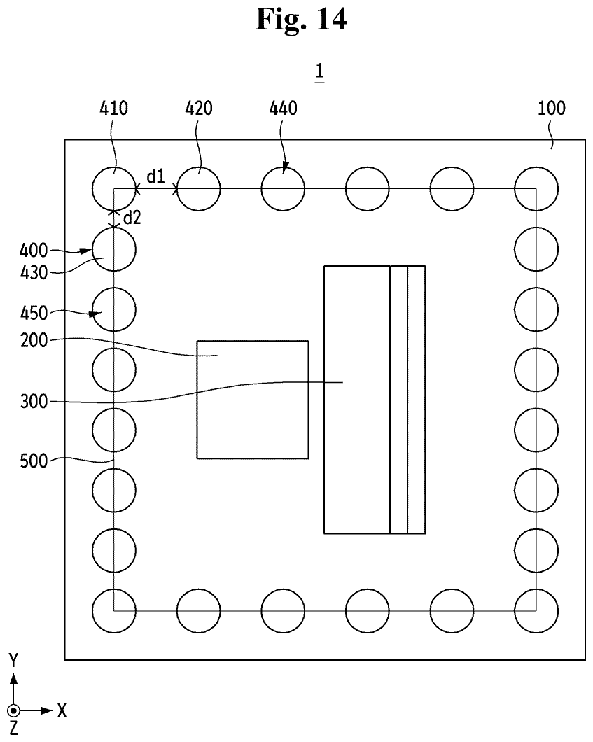

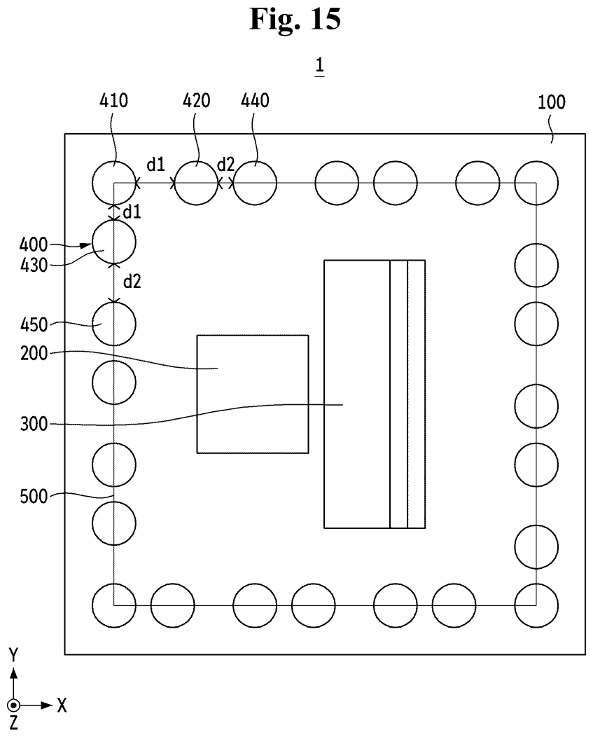

FIGS. 14 and 15 are top views illustrating semiconductor packages according to some embodiments. FIGS. 14 and 15 correspond to FIG. 1, and thus, for convenience, the embodiments of FIGS. 14 and 15 will hereinafter be described, the descriptions omitting the same descriptions of features as the ones explained in FIG. 1 and focusing mainly on the differences from the embodiment of FIG. 1.

Referring to FIG. 14, first conductive structures 400 may be disposed on a package substrate 100. The first conductive structures 400 may surround a first semiconductor chip 200 and a second semiconductor chip 300.

For example, the first conductive structures 400 may include a first conductive unit 410, a second conductive unit 420, and a third conductive unit 430 that are adjacent to one another.

The second conductive unit 420 may be adjacent to the first conductive unit 410 in a first direction X. A fourth conductive unit 440 may be adjacent to the second conductive unit 420, and the first conductive structures 400 may include a plurality of fourth conductive units 440 arranged in the first direction X. The distance between the first conductive unit 410 and the second conductive unit 420 adjacent to the first conductive unit 410 may be d1. The distance between the second conductive unit 420 and the fourth conductive unit 440 adjacent to the second conductive unit 420 may be d1. The distance between adjacent fourth conductive units 440 may be d1. For example, first conductive structures 400 arranged in the first direction X may all be arranged at equal intervals.

The first conductive unit 410 may be adjacent to the third conductive unit 430 in a second direction Y. A fifth conductive unit 450 may be adjacent to the third conductive unit 430, and the first conductive structures 400 may include a plurality of fifth conductive units arranged in the second direction Y. The distance between the first conductive unit 410 and the third conductive unit 430 adjacent to the first conductive unit 410 may be d2. The distance between the third conductive unit 430 and the fifth conductive unit 450 adjacent to the third conductive unit 430 may be d2. The distance between adjacent fifth conductive units 450 may be d2. For example, first conductive structures 400 arranged in the second direction Y may all be arranged at equal intervals.

Here, d1 and d2 may be in a range from 1/50 to 1/20 of an operating wavelength λ required and/or used for the operation of the first semiconductor chip 200 and/or the second semiconductor chip 300. For example, the operating wavelength λ may be determined based on the frequency of a reference clock provided from the first semiconductor chip 200 to the second semiconductor chip 300.

In some embodiments, d1 and d2 may have different values. For example, the distance between the first conductive structures 400 arranged in the first direction X and the distance between the first conductive structures 400 arranged in the second direction Y may differ. However, the inventive concept is not limited to this.

Referring to FIG. 15, first conductive structures 400 may be disposed on a package substrate 100. The first conductive structures 400 may surround a first semiconductor chip 200 and a second semiconductor chip 300.

For example, the first conductive structures 400 may include a first conductive unit 410, a second conductive unit 420, and a third conductive unit 430 that are adjacent to one another.

The second conductive unit 420 may be adjacent to the first conductive unit 410 in a first direction X. A fourth conductive unit 440 may be adjacent to the second conductive unit 420. The distance between the first conductive unit 410 and the second conductive unit 420 adjacent to the first conductive unit 410 may be d1. The distance between the second conductive unit 420 and the fourth conductive unit 440 adjacent to the second conductive unit 420 may be d2, which is different from d1. For example, the distances between first conductive structures 400 arranged in the first direction X may alternate between d1 and d2.

The third conductive unit 430 may be adjacent to the first conductive unit 410 in a second direction Y. A fifth conductive unit 450 may be adjacent to the third conductive unit 430. The distance between the first conductive unit 410 and the third conductive unit 430 adjacent to the first conductive unit 410 may be d1. The distance between the third conductive unit 430 and the fifth conductive unit 450 may be d2, which is different from d1. For example, the distances between the first conductive structures 400 arranged in the second direction Y may alternate between d1 and d2.

Here, d1 and d2 may be in a range from 1/50 to 1/20 of an operating wavelength λ required and/or used for the operation of the first semiconductor chip 200 and/or the second semiconductor chip 300. For example, the operating wavelength λ may be determined based on the frequency of a reference clock provided from the first semiconductor chip 200 to the second semiconductor chip 300.

In some embodiments, d1 and d2 may have different values. For example, the first conductive structures 400 surrounding the first semiconductor chip 200 and the second semiconductor chip 300 may be arranged with alternating a narrow distance (e.g., d1) and a wide distance (e.g., d2). However, the inventive concept is not limited to this.

Even though different figures illustrate variations of exemplary embodiments and different embodiments disclose different features from each other, these figures and embodiments are not necessarily intended to be mutually exclusive from each other. Rather, features depicted in different figures and/or described above in different embodiments can be combined with other features from other figures/embodiments to result in additional variations of embodiments, when taking the figures and related descriptions of embodiments as a whole into consideration. For example, components and/or features of different embodiments described above can be combined with components and/or features of other embodiments interchangeably or additionally to form additional embodiments unless the context clearly indicates otherwise, and the present disclosure includes the additional embodiments.

While the embodiments of the present disclosure have been described above with reference to the accompanying drawings, the inventive concept is not limited to these embodiments and may be implemented in various other forms. It will be understood by those skilled in the art to which the present disclosure pertains that modifications to the technical spirit or essential features of the present disclosure may be made without departing from its scope. Therefore, the embodiments described above should be understood as illustrative rather than restrictive in all respects.

What is claimed is:

1. A semiconductor package comprising:
a substrate;
a plurality of semiconductor chips disposed on the substrate;
a plurality of first conductive structures surrounding the semiconductor chips;
a plurality of second conductive structures disposed on the first conductive structures and electrically connecting the first conductive structures;
a mold layer encapsulating the semiconductor chips, the first conductive structures, and portions of the second conductive structures; and
a shielding film disposed on the mold layer and in contact with uppermost portions of the second conductive structures that are not encapsulated by the mold layer,
wherein
the semiconductor chips include a first semiconductor chip, and a second semiconductor chip spaced apart from the first semiconductor chip, and
upper surfaces of the first conductive structures are positioned below an upper surface of the second semiconductor chip.

2. The semiconductor package of claim 1, wherein
external connection terminals are disposed on a lower surface of the substrate and are configured to be electrically connected to an outside of the semiconductor package, and
the semiconductor package is configured such that the first conductive structures are electrically connected to ground via the external connection terminals.

3. The semiconductor package of claim 1, wherein the first conductive structures include copper (Cu).

4. The semiconductor package of claim 1, wherein
the first conductive structures include a first conductive unit, a second conductive unit adjacent to the first conductive unit, and a third conductive unit adjacent to the first conductive unit, and
the second conductive structures include a first wire having opposite ends in contact with the first conductive unit and the second conductive unit, respectively, and a second wire having opposite ends in contact with the first conductive unit and the third conductive unit, respectively.

5. The semiconductor package of claim 4, wherein a distance between the first conductive unit and the second conductive unit is 1/20 to 1/50 of an operating wavelength of the semiconductor chips.

6. The semiconductor package of claim 5, wherein
the first conductive unit and the second conductive unit are adjacent in a first direction,
the second conductive unit is adjacent to a fourth conductive unit in the first direction and a plurality of fourth conductive units are arranged in the first direction,
the first conductive unit, the second conductive unit, and the fourth conductive units are arranged at intervals of a first distance,
the first conductive unit and the third conductive unit are adjacent in a second direction intersecting the first direction,
the third conductive unit is adjacent to a fifth conductive unit in the second direction and a plurality of fifth conductive units are arranged in the second direction,
the first conductive unit, the third conductive unit, and the fifth conductive units are arranged at intervals of a second distance, and
the first distance is equal to the second distance.

7. The semiconductor package of claim 5, wherein
the first conductive unit and the second conductive unit are adjacent in a first direction,
the second conductive unit is adjacent to a fourth conductive unit in the first direction and a plurality of fourth conductive units are arranged in the first direction,
the first conductive unit, the second conductive unit, and the fourth conductive units are arranged at intervals of a first distance,
the first conductive unit and the third conductive unit are adjacent in a second direction intersecting the first direction,
the third conductive unit is adjacent to a fifth conductive unit in the second direction and a plurality of fifth conductive units are arranged in the second direction,
the first conductive unit, the third conductive unit, and the fifth conductive units are arranged at intervals of a second distance, and
the first distance is different from the second distance.

8. The semiconductor package of claim 5, wherein
the first conductive structures further include a fourth conductive unit,
the first conductive unit, the second conductive unit, and the fourth conductive unit are sequentially arranged in a first direction, and
a distance between the first conductive unit and the second conductive unit is greater than a distance between the second conductive unit and the fourth conductive unit.

9. The semiconductor package of claim 4, wherein
the first wire includes a first extension portion sealed by the mold layer and in contact with the first conductive unit, a second extension portion sealed by the mold layer and in contact with the second conductive unit, and a bent portion connecting the first extension portion and the second extension portion and in contact with the shielding film.

10. The semiconductor package of claim 4, wherein the shielding film is electrically connected to the first wire and the second wire.

11. The semiconductor package of claim 1, wherein upper surfaces of the first conductive structures are positioned at a higher level than an upper surface of the first semiconductor chip.

12. A method of manufacturing a semiconductor package, comprising:
disposing a plurality of semiconductor chips on a substrate;
disposing a plurality of first conductive structures surrounding the semiconductor chips;
disposing second conductive structures on the first conductive structures to electrically connect the first conductive structures;
disposing a mold layer encapsulating the semiconductor chips, the first conductive structures, and portions of the second conductive structures excluding uppermost portions of the second conductive structures; and
disposing, on the mold layer, a shielding film in contact with the uppermost portions of the second conductive structures,
wherein
the first conductive structures include a first conductive unit, a second conductive unit, and a third conductive unit that are adjacent to one another, and
the second conductive structures include a first wire having both ends in contact with the first conductive unit and the second conductive unit respectively, and a second wire having both ends in contact with the first conductive unit and the third conductive unit respectively.

13. The method of claim 12, further comprising:
disposing external connection terminals on a lower surface of the substrate such that the external connection terminals are configured to connect the semiconductor package to an outside of the semiconductor package,
wherein the semiconductor package is configured such that the first conductive structures are electrically connected to ground via the external connection terminals.

14. The method of claim 12, wherein
the semiconductor chips include a first semiconductor chip, and a second semiconductor chip spaced apart from the first semiconductor chip and having an upper surface higher than an upper surface of the first semiconductor chip, and
upper surfaces of the first conductive structures are positioned below the upper surface of the second semiconductor chip.

15. The method of claim 12, wherein a distance between the first conductive unit and the second conductive unit is in a range from 1/20 to 1/50 of an operating wavelength of the semiconductor chips.

16. The method of claim 15, wherein
the first conductive structures further include a fourth conductive unit and a fifth conductive unit,
the first conductive unit and the second conductive unit are adjacent in a first direction,
the second conductive unit is adjacent to the fourth conductive unit in the first direction and a plurality of fourth conductive units are arranged in the first direction,
the first conductive unit, the second conductive unit, and the fourth conductive units are arranged at intervals of a first distance,
the first conductive unit and the third conductive unit are adjacent in a second direction intersecting the first direction,
the third conductive unit is adjacent to the fifth conductive unit in the second direction and a plurality of fifth conductive units are arranged in the second direction,
the first conductive unit, the third conductive unit, and the fifth conductive units are arranged at intervals of a second distance, and
the first distance is equal to the second distance.

17. The method of claim 15, wherein
the first conductive structures further include a fourth conductive unit,
the first conductive unit, the second conductive unit, and the fourth conductive unit are sequentially arranged in a first direction, and
a distance between the first conductive unit and the second conductive unit is greater than a distance between the second conductive unit and the fourth conductive unit.

18. The method of claim 12, wherein the first wire includes a first extension portion sealed by the mold layer and in contact with the first conductive unit, a second extension portion sealed by the mold layer and in contact with the second conductive unit, and a bent portion connecting the first extension portion and the second extension portion and in contact with the shielding film.

19. The method of claim 12, wherein the shielding film is electrically connected to the first wire and the second wire.

20. A semiconductor package comprising:
a substrate;
a plurality of semiconductor chips disposed on the substrate;
a plurality of first conductive structures surrounding the semiconductor chips;
a plurality of second conductive structures disposed on the first conductive structures and electrically connecting adjacent first conductive structures;
a mold layer encapsulating the semiconductor chips, the first conductive structures, and portions of the second conductive structures;
a shielding film disposed on the mold layer and in contact with uppermost portions of the second conductive structures that are not encapsulated by the mold layer; and
external connection terminals disposed on a lower surface of the substrate and configured to electrically connect the semiconductor package to an outside of the semiconductor package,
wherein
the semiconductor chips include a first semiconductor chip, and a second semiconductor chip spaced apart from the first semiconductor chip and having an upper surface at a higher level than an upper surface of the first semiconductor chip,
the first conductive structures are configured to be electrically connected to ground via the external connection terminals,
upper surfaces of the first conductive structures are positioned at a lower level than the upper surface of the second semiconductor chip,
the first conductive structures include a first conductive unit, a second conductive unit, and a third conductive unit adjacent each other,
a distance between the first conductive unit and the second conductive unit is in a range from 1/20 to 1/50 of an operating wavelength of the semiconductor chips,
the second conductive structures include a first wire having both ends in contact with the first conductive unit and the second conductive unit respectively, and a second wire having both ends in contact with the second conductive unit and the third conductive unit respectively,
the first wire includes a first extension portion sealed by the mold layer and in contact with the first conductive unit, a second extension portion sealed by the mold layer and in contact with the second conductive unit, and a bent portion connecting the first extension portion and the second extension portion and in contact with the shielding film, and
the shielding film is electrically connected to the first wire and the second wire.
